(19) United States
(12) Patent Application Publication
(10) Pub. No.: US 2018/0138332 A1
(43) Pub. Date: May 17, 2018

(54) Semi-polar LED Epitaxial Structure and Fabrication Method

(71) Applicant: XIAMEN SANAN OPTOELECTRONICS TECHNOLOGY CO., LTD., Xiamen (CN)

(72) Inventors: Chengxiao DU, Xiamen (CN); Jiansen ZHENG, Xiamen (CN); Jie ZHANG, Xiamen (CN); Chen-ke HSU, Xiamen (CN)

(73) Assignee: XIAMEN SANAN OPTOELECTRONICS TECHNOLOGY CO., LTD., Xiamen (CN)

(21) Appl. No.: 15/870,949

(22) Filed: Jan. 13, 2018

Related U.S. Application Data
(63) Continuation of application No. PCT/CN2016/111663, filed on Dec. 23, 2016.

(30) Foreign Application Priority Data
Jan. 18, 2016 (CN) 201610030332.3
Jan. 18, 2016 (CN) 201610030333.8

(51) Int. Cl. H01L 31/0236; H01L 31/18; H01L 31/0304

(52) U.S. Cl. CPC H01L 31/02366; B82Y 99/00; H01L 31/03044; H01L 31/1856

(57) ABSTRACT

A semi-polar LED epitaxial structure includes, from bottom to up: a sapphire substrate; a semiconductor bottom layer structure; and a semiconductor functional layer; wherein: a surface of the semiconductor bottom structure has V pits; and a side of the V pits is a semi-polar surface, corresponding to (1-101) family of crystal planes. A fabrication method includes: providing a sapphire substrate; growing a semiconductor bottom structure over the sapphire substrate to form V pits on a surface, wherein a side of the V pits is a semi-polar surface, corresponding to (1-101) family of crystal planes; and growing a semiconductor functional layer over the semi-polar surface of the semiconductor bottom structure.

### CROSS-REFERENCE TO RELATED APPLICATIONS

The present application is a continuation of, and claims priority to, PCT/CN2016/111663 filed on Dec. 23, 2016, which claims priority to Chinese Patent Application Nos. CN 201610030333.8 and CN 201610030332.3, both filed on Jan. 18, 2016. The disclosures of these applications are hereby incorporated by reference in their entirety.

### BACKGROUND

LED is a semiconductor solid light-emitting device, using semiconductor PN junction as the light emitting material for direct photovoltaic conversion. By far, polar GaN-based LED technology has been industrialized for over 20 years with tremendous improvements in performance. Yet, polar LED encounters performance bottleneck for photoelectric conversion efficiency can hardly improve dramatically after reaching 60%. At present, it is commonly believed that insurmountable polarization effect of polar LED device would influence LED light emitting efficiency. In recent years, numerous studies and literature reports have been made on semi-polar and non-polar materials and devices.

### SUMMARY

The inventors of the present disclosure have recognized that, main problems include that it is rather difficult to grow GaN materials on the semi-polar surface or non-polar surface.

Two common methods for obtaining the semi-polar and non-polar GaN materials are as shown below: one is to obtain semi-polar or non-polar GaN film through non-polar and semi-polar sapphire; and the second is to obtain corresponding device through homoepitaxy by slicing semi-polar and non-polar surface of a homogeneous substrate. Through the first technology, it is hard to obtain high material quality; and the second technology has high material quality but the cost is high. Selective area epitaxy is another complex technology for growing semi-polar surface or non-polar surface; then, fabricate semi-polar or non-polar device over the semi-polar surface after in-situ growth; this process is complex and requires auxiliary materials and second epitaxial growth. From this point of view, how to obtain high quality materials is the main barrier of semi-polar and non-polar LEDs.

Various embodiments of the present disclosure provide a semi-polar LED in-situ grown on the C-plane sapphire substrate and a fabrication method thereof, wherein, the surface of the semiconductor bottom structure is controlled to form a V pit (including nanometer V pit) over the sapphire plane or the patterned substrate through epitaxial growth to further fabricate a semiconductor functional layer at the V pit side to finally form a semi-polar LED epitaxial structure.

According to one aspect of the present disclosure, provide a semi-polar LED, comprising from bottom to up: a sapphire substrate, a semiconductor bottom structure and a semiconductor functional layer, wherein, the surface of the semiconductor bottom structure has a V pit, and the V pit side is a semi-polar surface, corresponding to (1-101) family of crystal planes.

In some embodiments, the sapphire substrate is a patterned sapphire substrate or a flat sapphire substrate.

In some embodiments, the sapphire substrate is a patterned sapphire substrate, wherein, the pattern density is consistent with the V pit density.

In some embodiments, the semiconductor bottom layer structure comprises a buffer layer, an u-GaN layer, an n-GaN layer or any combination thereof.

In some embodiments, the semiconductor functional layer material includes GaN-based semiconductor material.

According to a second aspect of the present disclosure, a fabrication method of a semi-polar LED includes: (1) providing a sapphire substrate; (2) growing a semiconductor bottom structure over the sapphire substrate to form a V pit on the surface, wherein, the V pit side is a semi-polar surface, corresponding to (1-101) family of crystal planes; and (3) growing a semiconductor functional layer over the semiconductor bottom structure.

In some embodiments, the sapphire substrate is a patterned sapphire substrate or a flat sapphire substrate.

In some embodiments, density of the V pit is adjusted by the pattern density of the patterned sapphire substrate.

In some embodiments, the semiconductor bottom layer structure comprises a buffer layer, an u-GaN layer, an n-GaN layer or any combination thereof.

In some embodiments, in step (2), control the growth temperature low (within 1,100° C.) and growth rate fast (above 3 μm/h) to form a V pit on the surface of the semiconductor bottom structure.

In some embodiments, quicken growth rate of the semi-polar surface in step (3) to 5-10 times of that of a conventional polar surface, or extend the growth time to 5-10 times of that of a conventional polar surface.

In some embodiments, the semiconductor functional layer material includes GaN-based semiconductor material.

According to a third aspect of the present disclosure, a semi-polar LED is provided, including from bottom to up: a sapphire substrate, a semiconductor bottom layer structure and a semiconductor functional layer, wherein: the surface of the semiconductor bottom structure has a nanometer V pit, wherein, the V pit side is a semi-polar surface, corresponding to (1-101) family of crystal planes.

In some embodiments, the sapphire substrate is a nanometer patterned sapphire substrate or a flat sapphire substrate.

In some embodiments, the sapphire substrate is a nanometer patterned sapphire substrate, and wire diameter size of the nanometer V pit is 100-1,000 nm.

In some embodiments, the sapphire substrate is a flat sapphire substrate, and wire diameter size of the nanometer V pit is in normal distribution, and peak size of normal distribution corresponds to 550±10 nm.

In some embodiments, the semiconductor bottom layer structure comprises a buffer layer, an u-GaN layer, an n-GaN layer or any combination thereof.

In some embodiments, the semiconductor functional layer material includes GaN-based semiconductor material.

In some embodiments, the semiconductor functional layer comprises a first semiconductor functional layer and a second semiconductor functional layer, wherein, the first semiconductor functional layer surface has a nanometer V pit.

According to a fourth aspect of the present invention, a fabrication method of a semi-polar LED is provided, comprising: (1) providing a sapphire substrate; (2) growing a semiconductor bottom structure over the sapphire substrate to form a nanometer V pit on the surface, wherein, the V pit side is a semi-polar surface, corresponding to (1-101) family of crystal planes; and (3) growing a semiconductor functional layer over the semiconductor bottom structure.

In some embodiments, the sapphire substrate is a nanometer patterned sapphire substrate or a flat sapphire substrate.

In some embodiments, density of the V pit is adjusted by the pattern density of the nanometer patterned sapphire substrate.

In some embodiments, the sapphire substrate is a nanometer patterned sapphire substrate, and wire diameter size of the nanometer V pit is 100-1000 nm.

In some embodiments, the sapphire substrate is a flat sapphire substrate, and wire diameter size of the nanometer V pit is in normal distribution, and peak size of normal distribution corresponds to 550±10 nm.

In some embodiments, the semiconductor bottom layer structure comprises a buffer layer, an uGaN layer, an nGaN layer or any combination thereof.

In some embodiments, in step (2), control the growth temperature low (within 1,100° C.) and growth rate fast (above 3 μm/h) to form a nanometer V pit on the surface of the semiconductor bottom structure.

In some embodiments, the semiconductor functional layer material includes GaN-based semiconductor material.

In some embodiments, the semiconductor functional layer comprises a first semiconductor functional layer and a second semiconductor functional layer, wherein, the first semiconductor functional layer surface has a nanometer V pit.

In some embodiments, the nanometer V pit of the first semiconductor functional layer is obtained by quickening growth rate of the semi-polar surface to 5-10 times of that of a conventional polar surface, or extend the growth time to 5-10 times of that of a conventional polar surface.

Compared with conventional technologies, the conduction band and the valence band of the LED epitaxial structure having a conventional polar surface (001) are bent due to polarization electric field, so that the reciprocal spaces of the bottom of the conduction band and the top of the valence band are not in a same position, which similarly changes to indirect band gap semiconductor light emitting (in the case of AlInGaN-based materials, it is direct band gap light emitting material). Consequently, the radiant composition light emitting efficiency is reduced, and non-radiant composition probability increases.

Various embodiments of the present disclosure can have one or more of the following technical effects: (1) the fabrication process is simplified as it requires neither selective area epitaxy nor secondary epitaxy; (2) the semi-polar surface is (1-101) family of crystal planes. The reciprocal spaces of the smooth bottom of the conduction band and the top of the valence band have large overlapping area, which greatly increases radiation compound efficiency; (3) the semi-polar surface is exposed by adjusting the material growth process without restricting substrate geometrical shape, thus fabricating a semi-polar surface material with high operability and low cost. (4) form a semiconductor functional layer over the surface of the semiconductor bottom structure having a nanometer V pit so that the obtained epitaxial structure can combine with the existing chip fabrication for facilitating semiconductor light-emitting devices such as LED chips.

### BRIEF DESCRIPTION OF THE DRAWINGS

The accompanying drawings, which are included to provide a further understanding of the invention and constitute a part of this specification, together with the embodiments, are therefore to be considered in all respects as illustrative and not restrictive. In addition, the drawings are merely illustrative, which are not drawn to scale.

In the drawings: 11, 21, 31, 41, 51, 61: sapphire substrate; 12, 22, 32, 42, 52, 62: buffer layer; 13, 23, 33, 43, 53, 63: first u-GaN layer; 14, 24, 34, 44, 54, 64: second u-GaN layer; 15, 25, 35, 45, 55, 65: n-GaN layer; 16, 26, 36, 46, 56, 66: semiconductor functional layer; 17, 27, 37, 47, 57, 67: V pit side (corresponding to the (1-101) family of crystal planes); 461: 661: first semiconductor functional layer; 462: 662: second semiconductor functional layer.

FIG. 1 is a sectional view illustrating a first step of fabricating the LED epitaxial structure fabricated according to Embodiment 1;

FIG. 2 illustrates a second step;

FIG. 3 illustrates a third step;

FIG. 4 illustrates a fourth step;

FIG. 5 is a sectional view of an LED epitaxial structure according to Embodiment 2;

FIG. 6 is a sectional view diagram of the LED epitaxial structure according to Embodiment 3;

FIG. 7 is a sectional view illustrating a first step of fabricating the LED epitaxial structure fabricated according to Embodiment 4;

FIG. 8 illustrates a second step;

FIG. 9 illustrates a third step;

FIG. 10 illustrates a fourth step;

FIG. 11 is a sectional view of an LED epitaxial structure according to Embodiment 5;

FIG. 12 is a sectional view diagram of the LED epitaxial structure according to Embodiment 6;

FIG. 13 is a sectional view diagram of the LED epitaxial structure according to Embodiment 7; and

FIG. 14 is a sectional view diagram of the LED epitaxial structure according to Embodiment 8 of the present disclosure.

### DETAILED DESCRIPTION

Various embodiments of the present disclosure will be explained in details with reference to the accompanying drawings. Before further description, it should be understood, however, that various modifications and changes may be made to these embodiments. Therefore, the present invention is not limited to the embodiments below. It should also be noted that the scope of the present disclosure should still be subjected to the scope defined in the claims and the embodiments are merely for purposes of illustration, rather than restricting. Unless otherwise specified, all technical and scientific words shall have the same meanings as understood by persons skilled in the art.

### Embodiment 1

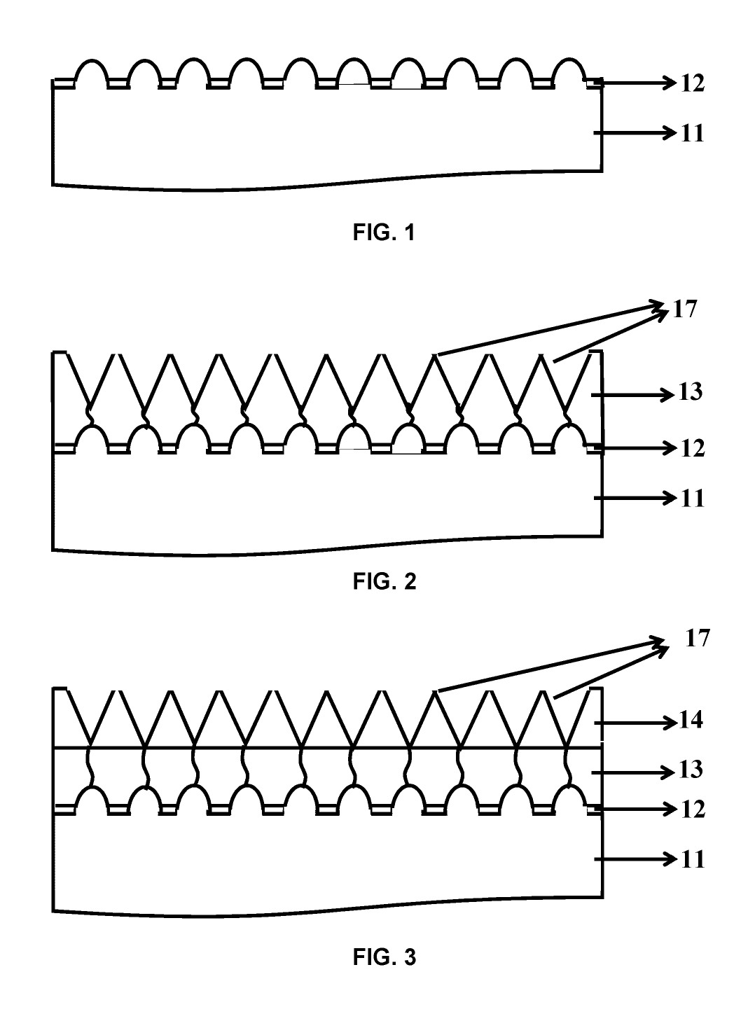

Referring to FIGS. 1-5, this embodiment provides a fabrication method of a GaN semi-polar LED, which addresses the problem of difficult growth of semi-polar materials and high cost of homogeneous semi-polar material. The technical scheme below takes a patterned sapphire substrate as an example. The fabrication method comprises steps below:

Referring to FIG. 1, provide a sapphire substrate 11 (Sapphire), and put it into a metal organic chemical vapor deposition (MOCVD) device; rise temperature to 1,000-1,200° C. for treating 3-10 minutes amid hydrogen atmosphere; employ a patterned sapphire substrate (PSS) to obtain a regular surface V pit (dent) array, which corresponds to each patterned substrate bulge (island). V pit density can be adjusted through pattern density of the patterned substrate. When the pattern density of the patterned substrate is determined, the V pit density is same, and then size of each V pit is determined, namely, the PSS pattern density is kept consistent with the V pit; employ a flat sapphire substrate (FSS) to obtain a semi-polar surface LED, where V pits on the surface are of different sizes and in random distribution; however, the density is influenced by buffer layer thickness and annealing conditions of the buffer layer: the thicker is the buffer layer, the lower is annealing temperature, and then, annealing time becomes shorter, island density is higher, and subsequent V pit density is higher; and vice versa. Lower temperature to 500-600° C., and input ammonia and trimethyl gallium, and grow a 20-50 nm AlInGaN low-temperature buffer layer 12 (buffer) for stress release; then, switch off trimethyl gallium; wherein, the epitaxial growth method can be CVD (chemical vapor deposition), PECVD (plasma enhanced chemical vapor deposition), MBE (molecular beam epitaxy), and HVPE (hydride vapor phase epitaxy). This embodiment prefers to use MOCVD, but is not limited to this method.

Referring to FIG. 2, grow a semiconductor bottom structure having a V pit over the low-temperature buffer layer 12 through epitaxial growth, wherein, the V pit side 17 is a semi-polar surface, corresponding to the (1-101) family of crystal planes. Specifically, rise temperature to 1,000-1,100° C., and anneal for 1-5 minute. Then, input trimethyl gallium for growing a 1-2 μm thick non-doping GaN 13 (the first uGaN layer); this layer is referred to as a 3D mode GaN growth layer; control growth temperature within 1,050° C., chamber pressure at 500 torr, and growth rate above 3 μm/h to obtain a large number of V pits. The V pits can cover the entire epitaxial surface, and the C plane is completely disappeared; or, the V pits can partially cover the surface; in this embodiment, it is preferred that the V pits cover the entire epitaxial surface, having no C plane.

Referring to FIG. 3, control temperature within 1,100° C. and chamber pressure at 300 torr to grow a 1-2 μm thick non-doping GaN 14 (the second uGaN layer). This layer is referred to as a 2D mode GaN growth layer; control growth rate above 4 μm/h, and the V pits cover the entire surface.

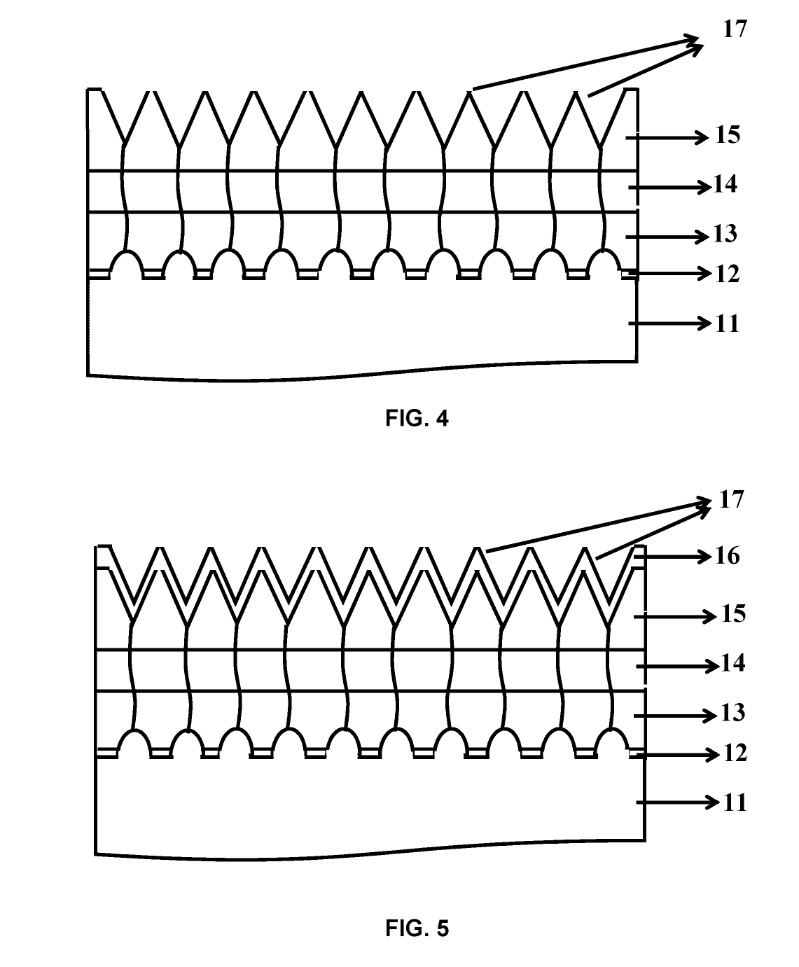

Referring to FIG. 4, lower temperature to about 1050° C., and chamber pressure at 300 torr; grow a 1.5-4 μm thick gallium nitride, and input silicane for doping to form an N-type GaN 15 (nGaN layer); or, grow an uGaN/nGaN superlattice to replace the fully doped nGaN; provide electronic injection; control growth rate above 5 μm/h; and after growth of nGaN, the epitaxial surface is fully occupied by the V pits.

Referring to FIG. 5, continue to grow a semiconductor functional layer over the surface of the semiconductor bottom structure having a V pit. In this embodiment, GaN-based semiconductor material is preferred, and the structural layer is SLs/MQWs/pAlGaN/pGaN/p++, which serves as the functional layer. Specifically, lower temperature to 770-870° C., and grow 15-30 circles of InGaN/GaN superlattice layers (SLs), wherein, InGaN thickness in each circle ranges from 1 to 3 nm, and GaN thickness range is 2.5-8 nm.

This superlattice layer serves as the low-temperature stress release layer for stress release; as epitaxial deposition rate of the semi-polar surface is only 1/10-⅕ that of the polar surface; fabricate an epitaxial layer having a thickness equivalent to that formed through a conventional method (polar growth); growth rate on the semi-polar surface can be quickened by 5-10 times by regulating source gas flow, or growth time is extended to 5-10 times that of conventional time; control temperature within 750-900° C., and continue to grow 5-15 circles of InGaN/GaN multiquantum well layers (MQWs), serving as the light emitting layer; growth rate is same as that of the low-temperature stress release layer (InGaN/GaN superlattice layer); control temperature within 800-950° C., and grow a p-type AlGaN electron blocking layer (pAlGaN) to block electron expansion; growth rate is same as that of the low-temperature stress release layer; rise temperature to 900-1050° C.; grow the p-type GaN layer (pGaN), and provide hole injection; the growth rate is same as that of the low-temperature pressure stress layer (InGaN/GaN superlattice layer); under 900-1,050° C., grow a heavily-doped p-type GaN contact layer (p++), which is easily for subsequent fabrication of common transparent electrode (such as ITO) of LED device to form ohmic contact; the growth rate is same as the treatment method of the low-temperature stress release layer (InGaN/GaN superlattice layer). It should be noted that, the p-type GaN layer and the heavily-doped p-type GaN contact layer (p++) require growth conditions different from the p-type layer of conventional C-plane LED. During growth of the p-type layer of a conventional C-plane LED, a large amount of hydrogen is input for filling (filling up) the V pit; in this embodiment, pGaN is grown in nitrogen conditions or little hydrogen to avoid filling up the V pit.

### Embodiment 2

Referring to FIG. 5, a LED epitaxial structure is provided, comprising from bottom to up: a sapphire substrate 11, a buffer layer 12, a semiconductor bottom structure having a V pit which comprises a first u-GaN layer 13, a second u-GaN layer 14 and an nGaN layer 15, and a semiconductor functional layer 16 comprising SLs/MQWs/pAlGaN/pGaN/p++.

Specifically, the sapphire substrate 11 in this embodiment can be a patterned sapphire substrate (PSS), or a flat sapphire substrate (FSS). In this embodiment, a PSS substrate is preferred. The limited range of characteristic size (circle) is 1-10 μm, but is not limited to this range.

The buffer layer 12 material is AlInGaN semiconductor layer, formed over the sapphire substrate 11, which eliminates the lattice mismatch caused by lattice constant difference between the sapphire substrate 11 and the first-conductive type semiconductor layer, thus improving epitaxial growth quality.

A semiconductor bottom structure having a V pit is formed over the buffer layer 12, wherein, the semiconductor bottom structure comprises from bottom to up: a 1-2 μm thick non-doping GaN 13 (the first uGaN layer), a 1-2 μm thick non-doping GaN 14 (the second uGaN layer) and a 1.5-4 μm thick N-type GaN 15 (nGaN layer). V pits are formed on the surface of each structure layer, wherein, the V pit side is a semi-polar surface, corresponding to (1-101) family of crystal planes.

SLs, MQWs, pAlGaN, pGaN and p++ form a semiconductor functional layer 16, which are formed on the nGaN surface of the V pits in successive.

### Embodiment 3

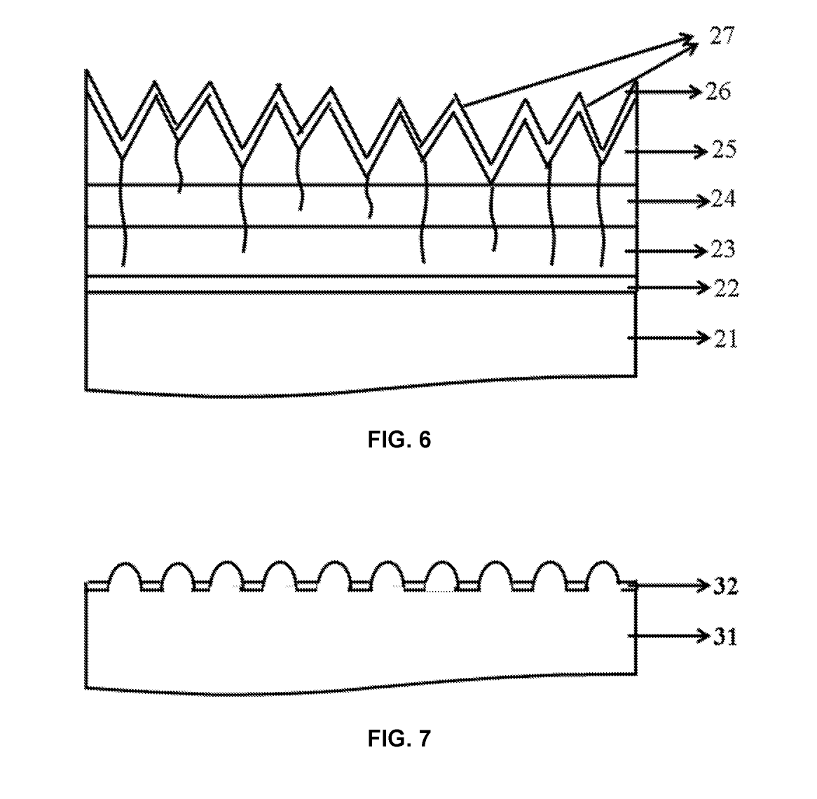

Referring to FIG. 6, the difference between this embodiment and Embodiment 1 is that: The first uGaN layer 13 with 3D mode growth of the patterned sapphire substrate in Embodiment 1 forms a 2D film between sapphire substrates (at the interval) and the pattern top forms a V pit; in this embodiment, after depositing a buffer layer 22 on the flat sapphire substrate, rise temperature to 1,000-1,100° C. Under this temperature, anneal for 1-5 minutes. Take the nucleation island on the sapphire substrate surface (not shown in the figure) as the nucleation center of the first uGaN layer 23; form a plurality of V pits with different sizes and in random distribution through 3D mode growth; later step is same as Embodiment 1.

To sum up, various embodiments of the present disclosure can simplify fabrication process as it requires neither selective area epitaxy nor secondary epitaxy; in addition, the semi-polar surface is a (1-101) family of crystal planes, reciprocal spaces of the smooth bottom of the conduction band and the top of the valence band have large overlapping area, which greatly increases radiation compound efficiency; the semi-polar surface is exposed by adjusting the material growth process without restricting substrate geometrical shape, thus fabricating a semi-polar surface material with high operability and low cost.

### Embodiment 4

Referring to FIGS. 7-12, this embodiment provides a fabrication method of GaN semi-polar LED epitaxial structure, which addresses the problem of difficult growth of semi-polar materials and high cost of homogeneous semi-polar material. The technical scheme below takes nanometer sapphire substrate as an example. The fabrication method comprises steps below:

Referring to FIG. 7, provide a nanometer patterned sapphire substrate 31 (Sapphire), and put it into a metal organic chemical vapor deposition (MOCVD) device, and rise temperature to 1,000-1,200° C. for treating 3-10 minutes under hydrogen atmosphere; use a nanometer patterned sapphire substrate (PSS) to obtain regular surface V pit (dent) array; the wire diameter of the PSS pattern is 100-1,000 nm, and pattern height is 300-2000 nm, and the interval is ⅕-½ of the circle size; under this size, the pattern neither influences existing chip fabrication nor subsequent photoetching process such as chip electrode fabrication. If the pattern wire diameter size is small (<100 nm), V pit is small, and low-temperature functional layers at the V pit bottom are overlapped, wherein, the overlapping portion occupies highly proportion of the inner wall of the entire V pit, which is of poor lighting, thus influencing lighting efficiency of the device, therefore, the size shall not be too small; if the wire diameter size of the pattern is too large (>1,000 nm), combination degree of the epitaxial structure and the existing chip process is low, which is not easy to fabricate a LED device; corresponding to each PSS bulge (island), density of the V pit can be adjusted according to the pattern density; when the pattern density of the patterned substrate is determined, the V pit density is same; and size of each V pit is determined correspondingly, and the wire diameter size of the V pit is 100-1,000 m; when a plane substrate is used, a semi-polar surface LED can be obtained, where, V pits on the surface are of different sizes and in random distribution; however, the density is influenced by buffer layer thickness and annealing conditions of the buffer layer: the thicker is the buffer layer, the lower is annealing temperature, and then, annealing time becomes shorter, island density is higher, and subsequent V pit density is higher; and vice versa. Lower temperature to 500-600° C., and input ammonia and trimethyl gallium, and grow a 20-50 nm AlInGaN low-temperature buffer layer 32 (buffer) for stress release; then, switch off trimethyl gallium; wherein, the epitaxial growth method can be CVD (chemical vapor deposition), PECVD (plasma enhanced chemical vapor deposition), MBE (molecular beam epitaxy), and HVPE (hydride vapor phase epitaxy). This embodiment prefers to use MOCVD, but is not limited to this method.

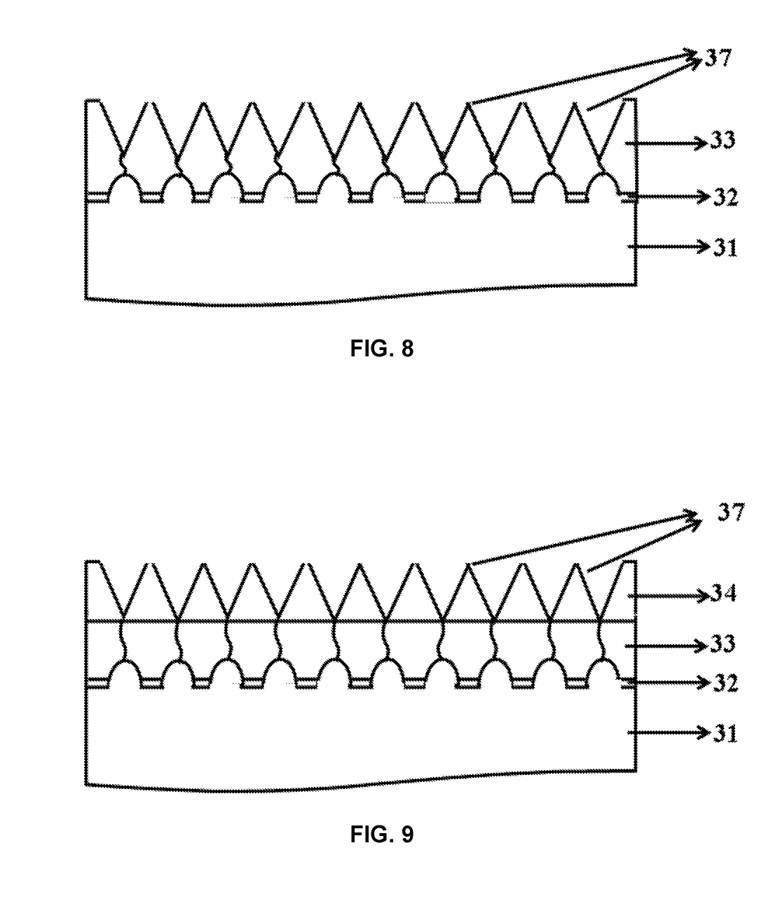

Referring to FIG. 8, grow a semiconductor bottom structure having a V pit over the low-temperature buffer layer 32 through epitaxial growth, wherein, the V pit side 17 is a semi-polar surface, corresponding to the (1-101) family of crystal planes. Specifically, rise temperature to 870-970° C., and anneal for 5 s-2 min. Then, input trimethyl gallium for growing a 1-2 μm thick non-doping GaN 33 (the first u-GaN layer); this layer is referred to as a 3D mode GaN growth layer; control growth temperature within 1,050° C., chamber pressure at 500 torr, and growth rate above 3 μm/h to obtain a large number of nanometer V pits. The V pits can cover the entire epitaxial surface, and the C plane is completely disappeared; or, the V pits can partially cover most of the surface; in this embodiment, it is preferred that the nanometer V pits cover the entire epitaxial surface, having no C plane.

Referring to FIG. 9, control temperature within 1,100° C. and chamber pressure at 300 torr to grow a 1-2 μm thick non-doping GaN 34 (the second uGaN layer). This layer is referred to as a 2D mode GaN growth layer; control growth rate above 4 μm/h, and the nanometer V pits cover the entire surface.

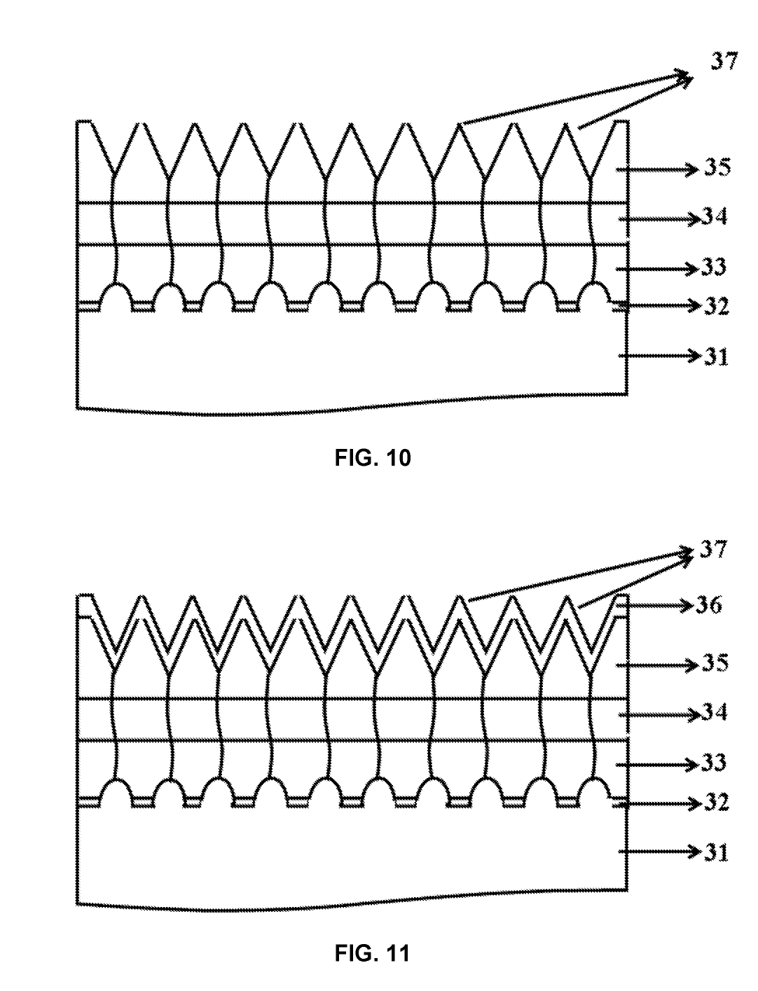

Referring to FIG. 10, lower temperature to about 1,050° C., and chamber pressure at 300 torr; grow a 1.5-4 μm thick gallium nitride, and input silicane for doping to form an N-type GaN 35 (nGaN layer); or, grow an uGaN/nGaN superlattice to replace the fully doped nGaN; provide electronic injection; control growth rate above 5 μm/h; and after growth of nGaN, the epitaxial surface is fully occupied by the nanometer V pits.

Referring to FIG. 11, continue to grow a semiconductor functional layer 36 over the surface of the semiconductor bottom structure having a nanometer V pit. In this embodiment, GaN-based semiconductor material is preferred, and the structural layer is SLs/MQWs/pAlGaN/pGaN/p++, which serves as the functional layer. Specifically, lower temperature to 770-870° C., and grow 15-30 circles of InGaN/GaN superlattice layers (SLs), wherein, InGaN thickness in each circle ranges from 1 to 3 nm, and GaN thickness range is 2.5-8 nm. This superlattice layer serves as the low-temperature stress release layer for stress release; as epitaxial deposition rate of the semi-polar surface is only 1/10-⅕ that of the polar surface, fabricate an epitaxial layer having a thickness equivalent to that formed through the conventional method (polar growth); growth rate on the semi-polar surface can be quickened by 5-10 times by regulating source gas flow, or growth time is extended to 5-10 times that of conventional time; control temperature within 750-900° C., and continue to grow 5-15 circles of InGaN/GaN multiquantum well layers (MQWs), serving as the light emitting layer; growth rate is same as that of the low-temperature stress release layer (InGaN/GaN superlattice layer); control temperature within 800-950° C., and grow a p-type AlGaN electron blocking layer (pAlGaN) to block electron expansion; growth rate is same as that of the low-temperature stress release layer; rise temperature to 900-1050° C.; grow the p-type GaN layer (pGaN), and provide hole injection; the growth rate is same as that of the low-temperature pressure stress layer (InGaN/GaN superlattice layer); under 900-1,050° C., grow a heavily-doped p-type GaN contact layer (p++), which is easily for subsequent fabrication of common transparent electrode (such as ITO) of LED device to form ohmic contact; the growth rate is same as the treatment method of the low-temperature stress release layer (InGaN/GaN superlattice layer). It should be noted that, the p-type GaN layer and the heavily-doped p-type GaN contact layer (p++) require growth conditions different from the p-type layer of conventional C-plane LED. During growth of the p-type layer of a conventional C-plane LED, a large amount of hydrogen is input for filling in the V pit; in this embodiment, pGaN is grown in nitrogen conditions or little hydrogen to avoid filling the V pit.

### Embodiment 5

Referring to FIG. 11, an LED epitaxial structure is provided, comprising from bottom to up: a sapphire substrate 31, a buffer layer 32, a semiconductor bottom structure having nanometer V pits, which comprises a first u-GaN layer 33, a second u-GaN layer 34 and an n-GaN layer 35, a semiconductor functional layer 36 comprising SLs/MQWs/pAlGaN/pGaN/p++ and an electrode structure (not shown).

Specifically, the sapphire substrate 31 in this embodiment can be a patterned sapphire substrate (PSS) or a flat sapphire substrate (FSS). The wire diameter of the PSS pattern is 100-1,000 nm, and pattern height is 300-2,000 nm, and the interval is ⅕-½ of the circle size; under this size, the pattern neither influences existing chip fabrication nor subsequent photoetching process such as chip electrode fabrication. If the pattern wire diameter size is small (<100 nm), V pit is small, and low-temperature functional layers at the V pit bottom are overlapped, wherein, the overlapping portion occupies highly proportion of the inner wall proportion of the entire V pit, which is of poor lighting, thus influencing lighting efficiency of the device, therefore, the size shall not be too small; if the wire diameter size of the pattern is too large (>1,000 nm), combination degree of the epitaxial structure and the existing chip process is low, which is not easy to fabricate a LED device.

The buffer layer 32 material is AlInGaN semiconductor layer, formed over the sapphire substrate 31, which eliminates the lattice mismatch caused by lattice constant difference between the sapphire substrate 31 and the first-conductive type semiconductor layer, thus improving epitaxial growth quality.

A semiconductor bottom structure having a nanometer V pit formed over the buffer layer 32, wherein, the semiconductor bottom structure comprises from bottom to up: a 1-2 μm thick non-doping GaN 33 (the first uGaN layer), 1-2 μm thick non-doping GaN 34 (the second uGaN layer) and a 1.5-4 μm thick N-type GaN 35 (nGaN layer). Nanometer V pits are formed on the surface of each structure layer, wherein, the V pit side is a semi-polar surface, corresponding to (1-101) family of crystal planes. The wire diameter size of the V pit is 100-1,000 nm.

The SLs, MQWs, pAlGaN, pGaN and p++ form a semiconductor functional layer 36, which are formed over the nGaN surface of the nanometer V pit to obtain corresponding nanometer V pit on the surface of the semiconductor functional layer 36. The epitaxial structure formed through this method can combine with the existing chip fabrication. In addition, the structure has surface roughening effect and the light extraction efficiency is high.

### Embodiment 6

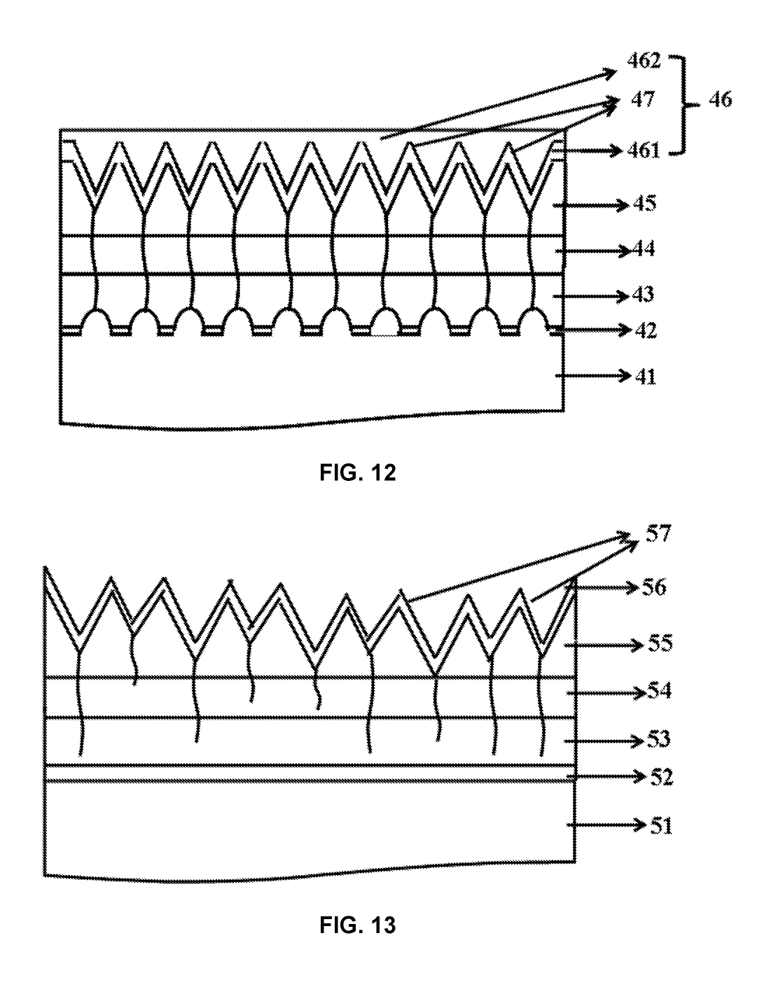

Referring to FIG. 12, the difference between this embodiment and Embodiment 4 is that: The surface of the semiconductor functional layer 36 in Embodiment 4 has nanometer V pit. The semiconductor functional layer 46 in this embodiment comprises a first semiconductor functional layer 461 and a second semiconductor functional layer 462, wherein, the first semiconductor functional layer 461 comprises SLs, MQWs and pAlGaN. The growth method is same as Embodiment 4, namely, quicken growth rate of the semi-polar surface to 5-10 times of the conventional polar surface or extend growth time to 5-10 times of the conventional polar surface to obtain nanometer V pits over the first semiconductor functional layer; the second semiconductor functional layer 462 comprises pGaN and p++, which employs conventional p-type GaN growth mode (2D mode growth with growth temperature surrounding 950° C. by inputting a large amount of H₂). Fill in surfaces of the nanometer V pits after the first semiconductor functional layer is grown so that the epitaxial structure can completely combine with conventional chip.

### Embodiment 7

Referring to FIG. 13, the difference between this embodiment and Embodiment 4 is that: The first u-GaN layer with 3D mode growth of the patterned sapphire substrate in Embodiment 4 forms a 2D film between sapphire substrates (at the interval) and the pattern top forms a V pit; in this embodiment, after depositing a buffer layer 52 on the flat sapphire substrate (FSS) 51, rise temperature to 990-1,000° C. Under this temperature, anneal for 5 s-5 minutes. Take the nucleation island on the sapphire substrate surface (not shown in the figure) as the nucleation center of the first u-GaN layer 53. Use 3D mode for growth so as to grow a plurality of nanometer V pits with different sizes and in random distribution. For nanometer sapphire pattern substrate, density of the nanometer V pit directly corresponds to the sapphire pattern circle; for flat sapphire substrate, density of the nanometer V pit depends on growth conditions of the buffer layer; by controlling growth temperature and rate, a large number of nanometer V pits of different sizes are formed in random; the wire diameter size of the nanometer V pit is in normal distribution, and peak size of normal distribution corresponds to 550±10 nm. In some too small V pits (such as less than 100 nm), light emitting efficiency is poor; in some too big V pits (such as approximate 1,000 nm), it brings negative effect on chip fabrication, and influences light-emitting device performance; subsequent embodiments are same as Embodiment 4.

### Embodiment 8

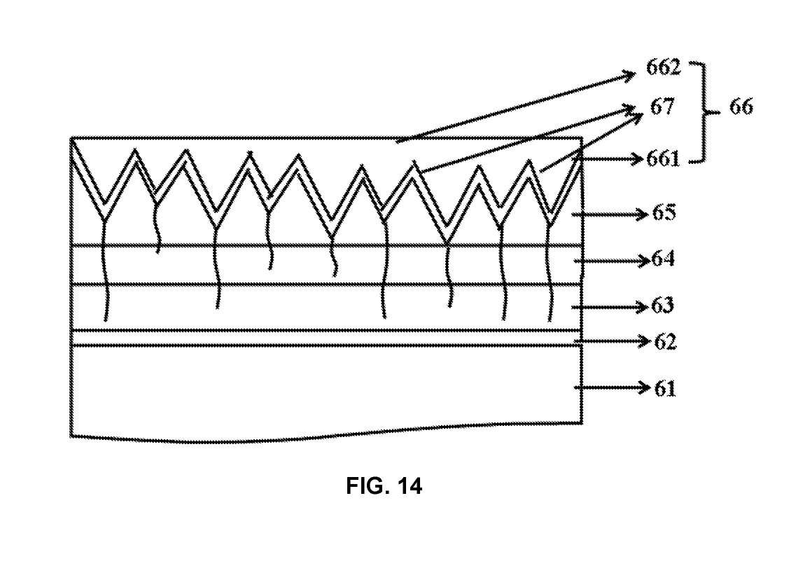

Referring to FIG. 14, the difference between this embodiment and Embodiment 6 is that: The sapphire substrate 41 in Embodiment 6 is a patterned sapphire substrate (PSS), and the sapphire substrate 61 in this embodiment is a flat sapphire substrate (FSS).

To sum up, various embodiments of the present disclosure control growth conditions of the bottom layer structure to control size/distribution of V pits, and matches subsequent design of semiconductor functional layer to combine with conventional chip fabrication. It simplifies fabrication process as it requires neither selective area epitaxy nor secondary epitaxy; in addition, the semi-polar surface is a (1-101) family of crystal planes, and reciprocal spaces of the smooth bottom of the conduction band and the top of the valence band have large overlapping area, which greatly increases radiation compound efficiency; the semi-polar surface is exposed by adjusting the material growth process without restricting substrate geometrical shape, thus fabricating a semi-polar surface material with high operability and low cost.

Although specific embodiments have been described above in detail, the description is merely for purposes of illustration. It should be appreciated, therefore, that many aspects described above are not intended as required or essential elements unless explicitly stated otherwise. Various modifications of, and equivalent acts corresponding to, the disclosed aspects of the exemplary embodiments, in addition to those described above, can be made by a person of ordinary skill in the art, having the benefit of the present disclosure, without departing from the spirit and scope of the disclosure defined in the following claims, the scope of which is to be accorded the broadest interpretation so as to encompass such modifications and equivalent structures.

1. A semi-polar LED epitaxial structure, comprising from bottom to up:
a sapphire substrate;
a semiconductor bottom layer structure; and
a semiconductor functional layer;
wherein:
a surface of the semiconductor bottom structure has V pits; and
a side of the V pits is a semi-polar surface, corresponding to (1-101) family of crystal planes.

2. The semi-polar LED epitaxial structure of claim 1, wherein the sapphire substrate is a patterned sapphire substrate or a flat sapphire substrate.

3. The semi-polar LED epitaxial structure of claim 1, wherein the sapphire substrate is a patterned sapphire substrate, wherein, the pattern density is consistent with the V pit density.

4. The semi-polar LED epitaxial structure of claim 1, wherein the semiconductor bottom layer structure comprises a buffer layer, an u-GaN layer, an n-GaN layer or any combination thereof.

5. The semi-polar LED epitaxial structure of claim 1, wherein the semiconductor functional layer material includes GaN-based semiconductor material.

6. The semi-polar LED epitaxial structure of claim 1, wherein the V pits are nanometer V pits, wherein.

7. The semi-polar LED epitaxial structure of claim 6, wherein the sapphire substrate is a nanometer patterned sapphire substrate, and wire diameter size of the nanometer V pits is 100-1000 nm.

8. The semi-polar LED epitaxial structure of claim 6, wherein the sapphire substrate is a flat sapphire substrate, and wire diameter size of the nanometer V pits is in normal distribution, and peak size of normal distribution corresponds to 550±10 nm.

9. The semi-polar LED epitaxial structure of claim 6, wherein the semiconductor functional layer comprises a first semiconductor functional layer and a second semiconductor functional layer, and the first semiconductor functional layer surface has the nanometer V pits.

10. A fabrication method of a semi-polar LED epitaxial structure, the method comprising:
(1) providing a sapphire substrate;
(2) growing a semiconductor bottom structure over the sapphire substrate to form V pits on a surface, wherein a side of the V pits is a semi-polar surface, corresponding to (1-101) family of crystal planes; and
(3) growing a semiconductor functional layer over the semi-polar surface of the semiconductor bottom structure.

11. The fabrication method of claim 10, wherein: the sapphire substrate is a patterned sapphire substrate, and density of the V pit is adjusted by the pattern density of the patterned sapphire substrate.

12. The fabrication method of claim 10, wherein the semiconductor bottom layer structure comprises a buffer layer, an u-GaN layer, an n-GaN layer or any combination thereof.

13. The fabrication method of claim 10, wherein in step (2), control the growth temperature low (within 1,100° C.) and growth rate fast (above 3 μm/h) to form a V pit on the surface of the semiconductor bottom structure.

14. The fabrication method of claim 10, wherein increase growth rate of the semi-polar surface in step (3) to 5-10 times of that of a conventional polar surface, or extend the growth time to 5-10 times of that of a conventional polar surface.

15. The fabrication method of claim 10, wherein the V pits are nanometer V pits.

16. The fabrication method of claim 15, wherein the sapphire substrate is a nanometer patterned sapphire substrate, and density of the V pit is adjusted by the pattern density of the nanometer patterned sapphire substrate.

17. The fabrication method of claim 15, wherein the sapphire substrate is a nanometer patterned sapphire substrate, and wire diameter size of the nanometer V pit is 100-1000 nm.

18. The fabrication method of claim 15, wherein the sapphire substrate is a flat sapphire substrate, and wire diameter size of the nanometer V pit is in normal distribution, and peak size of normal distribution corresponds to 550±10 nm.

19. The fabrication method of claim 15, wherein in step (2), control the growth temperature low (within 1100° C.) and growth rate fast (above 3 μm/h) to form a nanometer V pit on the surface of the semiconductor bottom structure.

20. The fabrication method of claim 15, wherein:
the semiconductor functional layer comprises a first semiconductor functional layer and a second semiconductor functional layer, wherein, the first semiconductor functional layer surface has the nanometer V pits; and
the nanometer V pits of the first semiconductor functional layer are obtained by quickening growth rate of the semi-polar surface to 5-10 times of that of a conventional polar surface, or extend the growth time to 5-10 times of that of a conventional polar surface.
